(19) United States
(12) Patent Application Publication
(10) Pub. No.: US 2022/0081514 A1
(43) Pub. Date: Mar. 17, 2022

(54) MODIFIED BISMALEIMIDE RESIN, METHOD FOR PREPARING THE SAME, PREPREG, COPPER CLAD LAMINATE AND PRINTED CIRCUIT BOARD

(71) Applicant: NAN YA PLASTICS CORPORATION, TAIPEI (TW)

(72) Inventors: TE-CHAO LIAO, TAIPEI (TW); SEN-HUANG HSU, TAIPEI (TW); Pei-Han Liu, New Taipei City (TW)

(21) Appl. No.: 17/378,779

(22) Filed: Jul. 19, 2021

(30) Foreign Application Priority Data
Sep. 16, 2020 (TW) 109131803

(51) Int. Cl. C08G 73/10; C08G 73/12; C08J 5/24; H05K 1/09; H05K 1/03

(52) U.S. Cl. CPC C08G 73/1003; C08G 73/128; C08J 5/24; H05K 2201/0358; H05K 1/0366; C08J 2379/08; H05K 2201/0154; H05K 1/09

(57) ABSTRACT

A modified bismaleimide resin, a method for preparing the same, a prepreg, a copper clad laminate, and a printed circuit board are provided. The modified bismaleimide resin is formed by a reaction between a diamine compound having a nonpolar backbone structure and maleic anhydride, and a molecular structure thereof contains a greater amount of non-polar and hydrophobic groups.

### CROSS-REFERENCE TO RELATED PATENT APPLICATION

This application claims the benefit of priority to Taiwan Patent Application No. 109131803, filed on Sep. 16, 2020. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a bismaleimide resin, and more particularly to a modified bismaleimide resin having better comprehensive performance, a method for preparing the same, and applications thereof, such as a prepreg, a copper clad laminate, and a printed circuit board.

### BACKGROUND OF THE DISCLOSURE

In recent years, as electronic products have developed toward multi-functionality and miniaturization, the requirements for circuit boards have also increased. Therefore, there is a tendency for the circuit boards to have a multi-layered design, a high density wiring, and a high speed signal transmission structure. Dielectric properties of a polymer material, such as a dielectric constant (Dk) and a dissipation factor (Df), are important indicators that affect signal transmission speed and signal quality. In terms of the transmission speed, when the polymer material has a lower dielectric constant, a faster signal transmission speed can be achieved. In terms of signal integrity, when the polymer material has a lower dissipation factor, a reduced signal transmission loss can be achieved. In certain applications (such as in high frequency printed circuit boards), apart from a very low dielectric constant (Dk) and dissipation factor (Df), the polymer material also needs to have high heat resistance, good molding processability, excellent comprehensive mechanical performance, and resistance to environmental aging.

Copper clad laminate (CCL) is a base material of a printed circuit board, and a composition thereof includes one or more thermoplastic resins, one or more reinforcing materials, and one or more copper foils. Although the thermoplastic resins (such as polyimide (PI), polyphenylene ether, polytetrafluoroethylene, polystyrene, ultra-high molecular weight polyethylene, polyphenylene sulfide and polyether ketone) have excellent electrical properties and good toughness, they are poor in molding processability and solvent solubility. Furthermore, the resins are unfavorable for processing and are thus limited in application since they have a higher melting point, higher melt viscosity, and poor adhesion to fibers. In addition, epoxy resins, phenolic resins, unsaturated polyesters, etc., have poor heat resistance and humidity resistance, and have a high dissipation factor, so that they cannot easily meet the requirements of certain special applications.

Based on a compact and robust structure, bismaleimide (BMI) has excellent dielectric properties and physical properties that include good thermal stability, strong mechanical properties, high glass transition temperature (Tg), and high toughness, and is often used for the copper clad laminates. However, a bismaleimide resin with a general structure has low brittleness and toughness, which result in poor processability. Moreover, the bismaleimide resin with the general structure also has a lower solvent solubility and a higher dielectric constant, and is thus inapplicable in certain situations.

To improve applicability, the BMI needs to be modified in at least one of multiple ways. For example, the BMI may be modified by aromatic diamines, epoxy resins, thermoplastic resins, rubbers, sulfur compounds, and allyl compounds. Furthermore, a number of BMIs having different structures may be used together for modification, and a chain extension or synthesis approach may be used for modification. Although a modified BMI exhibit improvement(s) in one or more properties, it cannot provide a balance between different properties required for a target application. For example, while the modified BMI is enhanced in toughness, its dielectric constant and dissipation factor cannot be lowered.

### SUMMARY OF THE DISCLOSURE

In response to the above-referenced technical inadequacies, the present disclosure provides a modified bismaleimide resin and a method for preparing the same. The modified bismaleimide resin has better comprehensive performance, and can thus meet practical requirements. The present disclosure also provides applications of the modified bismaleimide resin, such as a prepreg, a copper clad laminate, and a printed circuit board.

In one aspect, the present disclosure provides a modified bismaleimide resin having a structure represented by formula (1):

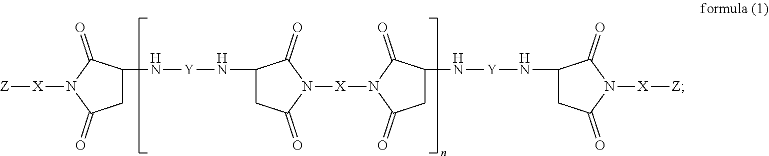

where X and Y each independently represent a group represented by formula (2) or (3), Z represents a group represented by formula (4), (5) or (6), and n represents an integer from 1 to 20;

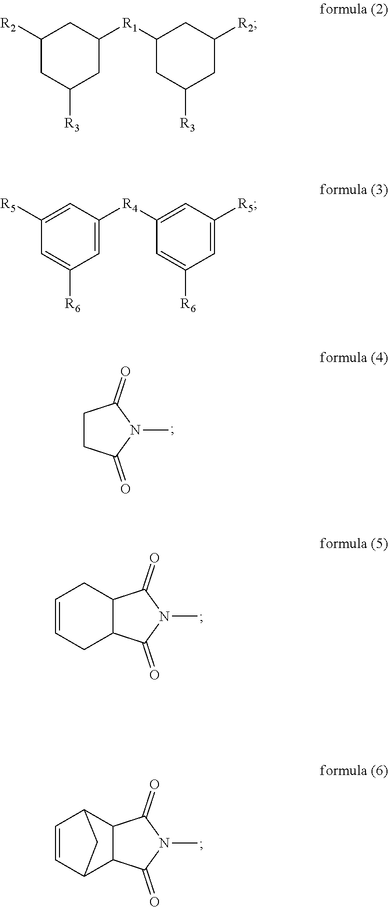

R₁ in formula (2) and R₄ in formula (3) each independently represent a benzyl group or an alkyl group having 1 to 10 carbon atoms, and R₂ and R₃ in formula (2) and R₅ and R₆ in formula (3) each independently represent a hydrogen atom or an alkyl group having 1 to 10 carbon atoms.

In one embodiment of the present disclosure, the modified bismaleimide resin has a dielectric constant (Dk) of less than 2.6 and a dissipation factor (Df) of less than 0.003 at 10 GHz.

In one embodiment of the present disclosure, a water absorption rate of the modified bismaleimide resin is 0.1% to 0.3%.

In one embodiment of the present disclosure, the modified bismaleimide resin has a solubility in acetone of 42% and a solubility in butanone of 40%.

In one embodiment of the present disclosure, a prepreg is further provided, and is obtained by applying a resin material onto a substrate and curing the resin material. The resin material includes the modified bismaleimide resin that has the structure represented by formula (1).

In one embodiment of the present disclosure, a copper clad laminate is further provided, and includes the prepreg and a copper foil layer attached to the prepreg. The prepreg uses the modified bismaleimide resin that has the structure represented by formula (1).

In one embodiment of the present disclosure, a printed circuit board is further provided, and is obtained by patterning the copper foil layer of the copper clad laminate into a circuit.

In another aspect, the present disclosure provides a method for preparing the modified bismaleimide resin that has the structure represented by formula (1), which includes: providing a reactor; placing a reaction solution into the reactor, in which the reaction solution includes a diamine compound, maleic anhydride, and a solvent, and a molar ratio of the diamine compound to the maleic anhydride is 1:2-20; and adding a catalyst into the reaction solution to carry out a synthesis reaction between the diamine compound and the maleic anhydride.

In one embodiment of the present disclosure, the diamine compound has a structure represented by formula (7), (8), (9), (10), or (11):

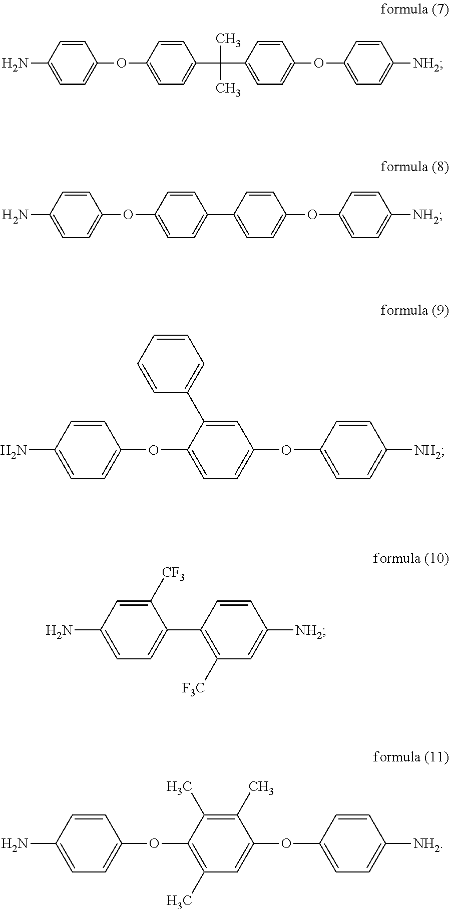 [SMILES: CC(C)(c1ccc(Oc2ccc(N)cc2)cc1)c1ccc(Oc2ccc(N)cc2)cc1 ; Nc1ccc(Oc2ccc(-c3ccc(Oc4ccc(N)cc4)cc3)cc2)cc1 ; Nc1ccc(Oc2ccc(Oc3ccc(N)cc3)c(-c3ccccc3)c2)cc1 ; Nc1ccc(-c2ccc(N)cc2C(F)(F)F)c(C(F)(F)F)c1 ; Cc1cc(Oc2ccc(N)cc2)c(C)c(C)c1Oc1ccc(N)cc1]

In one embodiment of the present disclosure, the synthesis reaction is carried out at 40° C. to 200° C. for 1 to 8 hours.

In one embodiment of the present disclosure, the solvent is acetone, toluene, N,N-dimethylformamide (DMF) or methyl isobutyl ketone (MIBK), and the catalyst includes sodium acetate, acetic anhydride and triethylamine.

Compared to a conventional bismaleimide resin, the modified bismaleimide resin of the present disclosure has the following beneficial properties. The modified bismaleimide resin has a molecular structure that contains a greater amount of non-polar and hydrophobic groups, thus having an improved brittleness, an increased toughness, and an increased solvent solubility. In practice, the modified bismaleimide resin has a solubility in acetone of 42% and a solubility in butanone of 40%. In addition, the modified bismaleimide resin is not easily polarized in an electric field, and has low dielectric properties. In practice, the modified bismaleimide resin has a dielectric constant (Dk) of less than 2.6 and a dissipation factor (Df) of less than 0.003 at 10 GHz.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a flowchart of a method for preparing a modified bismaleimide resin of the present disclosure;

FIG. 2 is a schematic view showing a manufacturing process of a prepreg of the present disclosure;

FIG. 3 is a schematic view showing a structure of the prepreg of the present disclosure;

FIG. 4 is a schematic view showing a manufacturing process of a copper clad laminate of the present disclosure; and

FIG. 5 is a schematic view showing a structure of a printed circuit board of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a”, “an”, and “the” includes plural reference, and the meaning of “in” includes “in” and “on”. Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first”, “second” or “third” can be used to describe various components, signals or the like, which are for distinguishing one component/signal from another one only, and are not intended to, nor should be construed to impose any substantive limitations on the components, signals or the like.

In order to improve properties of a bismaleimide resin for purposes of meeting practical requirements, the present disclosure modifies the bismaleimide resin. More specifically, the present disclosure uses a diamine compound having a nonpolar backbone structure to react with maleic anhydride in a synthesis reaction, and a modified bismaleimide resin thus obtained has a structure represented by formula (1):

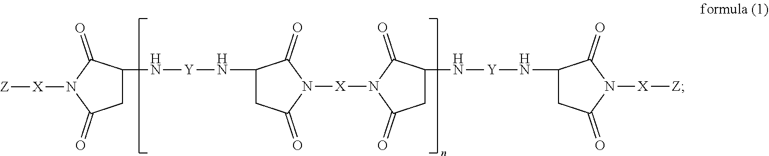

in formula (1), X and Y each independently represent a group represented by formula (2) or (3), Z represent a group represented by formula (4), (5) or (6), and n represents an integer from 1 to 20;

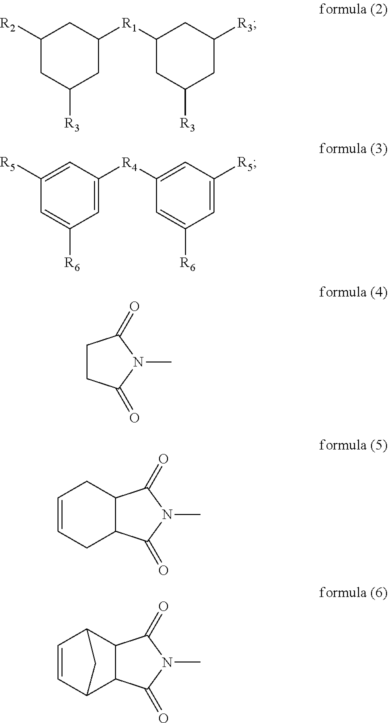

R₁ in formula (2) and R₄ in formula (3) each independently represent a benzyl group or an alkyl group having 1 to 10 carbon atoms, and R₂ and R₃ in formula (2) and R₅ and R₆ in formula (3) each independently represent a hydrogen atom or an alkyl group having 1 to 10 carbon atoms.

It should be noted that, the modified bismaleimide resin is a linear polymer, and a molecular structure thereof contains a greater amount of non-polar and hydrophobic groups, thus improving certain properties (such as brittleness, toughness, solvent solubility, electrical properties, and water absorbency). It is confirmed by experiments that, the modified bismaleimide resin has a solubility in acetone of 42% and a solubility in butanone of 40%. Furthermore, the modified bismaleimide resin has a dielectric constant (Dk) of less than 2.6 and a dissipation factor (Df) of less than 0.003 at 10 GHz. In addition, a water absorption rate of the modified bismaleimide resin is 0.1% to 0.3%.

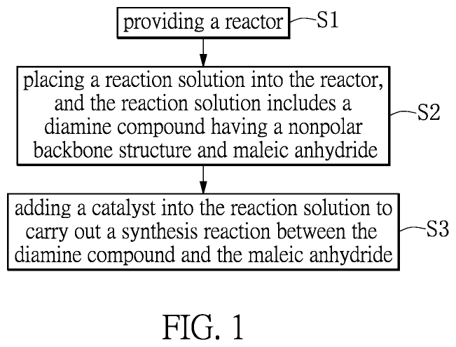

Referring to FIG. 1, the modified bismaleimide resin of the present disclosure is prepared by the following steps: providing a reactor in step S1; placing a reaction solution into the reactor in step S2, where the reaction solution includes a diamine compound having a nonpolar backbone structure and maleic anhydride; and adding a catalyst into the reaction solution to carry out a synthesis reaction between the diamine compound and the maleic anhydride in step S3.

More specifically, the reactor can have a stirring mixer disposed therein for stirring the reaction solution, and ingredients in the reaction solution are therefore mixed together. When preparing the reaction solution, the diamine compound and the maleic anhydride can be dissolved in a solvent that is preferably a polar aprotic solvent, such as acetone, toluene, N,N-dimethylformamide (DMF) or methyl isobutyl ketone (MIBK). Preferably, a molar ratio of the diamine compound to the maleic anhydride is 1:2-20. The diamine compound has a structure represented by formula (7), (8), (9), (10), or (11):

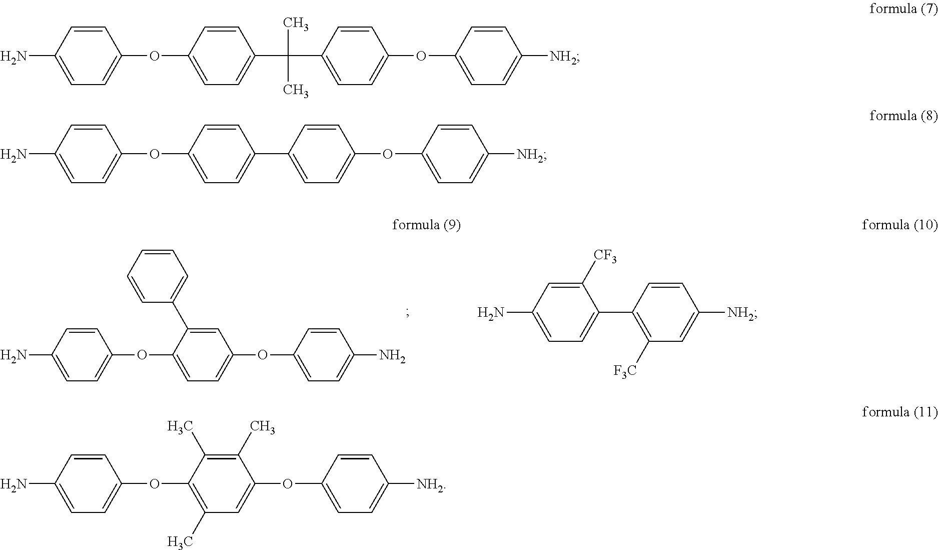

In step S3, the catalyst includes sodium acetate, acetic anhydride and triethylamine, and the diamine compound and the maleic anhydride undergo a Michael addition reaction in the presence of the catalyst. Reaction conditions include normal pressure, a reaction temperature from 40° C. to 200° C., and a reaction time from 1 to 8 hours. A bismaleamic acid is produced in the reaction solution after about 1 to 3 hours of reaction, and is then formed into a bismaleimide resin after the reaction is continued for another 1 to 5 hours. In practice, nitrogen gas can be introduced into the reactor before the initiation of the reaction, so as to remove air and moisture in the reactor. Furthermore, a dehydrating agent can be used in the reaction to remove water generated thereby, so as to increase a conversion rate of the reaction. The dehydrating agent can be a p-toluenesulfonate. However, the above description is only exemplary, and is not intended to limit the scope of the present disclosure.

After the reaction is completed, a weak base solution (such as a sodium bicarbonate aqueous solution) can be used to neutralize the reaction solution, and an alcohol is then used to precipitate resin particles or solution. Subsequently, the reaction solution is filtered and vacuum dried to obtain a powdered solid product of the bismaleimide resin.

### Example 1

164 g of a diamine compound having a structure represented by formula (7) (hereinafter referred to as “diamine compound A”) and 9.8 g of maleic anhydride are dissolved in 500 ml of toluene to prepare a reaction solution. A molar ratio of the diamine compound A to the maleic anhydride is 4:1. The reaction solution is placed into a 1000 ml four-neck round bottom reaction flask that has a stirring mixer disposed therein, and nitrogen gas is introduced into the 1000 ml four-neck round bottom reaction flask to remove air and moisture. The stirring mixer is turned on and operated at a rotation speed of 300 rpm under normal pressure, and the diamine compound A is fed in batches within half an hour.

A reaction temperature is raised to 60° C. to dissolve all the solids in the reaction solution. At this time, the reaction solution has a yellowish brown color. A catalyst including 4 g of sodium acetate, 140 ml of acetic anhydride, and 28 ml of triethylamine are added into the reaction solution. The reaction temperature is further raised to 90° C. to carry out a synthesis reaction between the diamine compound A and the maleic anhydride, and a reaction time is 8 hours. After the reaction is completed, the reaction solution is turned from the clear yellowish brown color into a viscous dark brown color. After a dark brown resin powder is precipitated from the reaction solution, impurities such as unreacted monomers and residuals of acid are removed from the dark brown resin powder, so that a high purity bismaleimide resin powder (hereinafter referred to as “BMI-A resin”) with a dark brown color is obtained. A physical property test is performed on a copper clad laminate made from the BMI-A resin, and test results are shown in Table 1.

### Example 2

147 g of a diamine compound having a structure represented by formula (8) (hereinafter referred to as “diamine compound B”) and 9.7 g of maleic anhydride are dissolved in 500 ml of N,N-dimethylformamide (DMF) to prepare a reaction solution. A molar ratio of the diamine compound B to the maleic anhydride is 4:1. The reaction solution is placed into a 1000 ml four-neck round bottom reaction flask that has a stirring mixer disposed therein, and nitrogen gas is introduced into the 1000 ml four-neck round bottom reaction flask to remove air and moisture. The stirring mixer is started and operated at a rotation speed of 300 rpm under normal pressure, and the diamine compound B is fed in batches within half an hour.

A reaction temperature is raised to 60° C. to dissolve all the solids in the reaction solution. At this time, the reaction solution has a yellowish brown color. A catalyst including 6 g of sodium acetate, 150 ml of acetic anhydride, and 30 ml of triethylamine are added into the reaction solution. The reaction temperature is further raised to 90° C. to carry out a synthesis reaction between the diamine compound B and the maleic anhydride, and a reaction time is 8 hours. After the reaction is completed, the reaction solution is turned from the clear yellowish brown color into a viscous dark brown color. After a dark brown resin powder is precipitated from the reaction solution, impurities such as unreacted monomers and residuals of acid are removed from the dark brown resin powder, so that a high purity bismaleimide resin powder (hereinafter referred to as “BMI-B resin”) with a dark brown color is obtained. A physical property test is performed on a copper clad laminate made from the BMI-B, and test results are shown in Table 1.

### Example 3

184 g of a diamine compound having a structure represented by formula (9) (hereinafter referred to as “diamine compound C”) and 12.38 g of maleic anhydride are dissolved in 450 ml of methyl isobutyl ketone (MIBK) to prepare a reaction solution. A molar ratio of the diamine compound C to the maleic anhydride is 4:1. The reaction solution is placed into a 1000 ml four-neck round bottom reaction flask that has a stirring mixer disposed therein, and nitrogen gas is introduced into the 1000 ml four-neck round bottom reaction flask to remove air and moisture. The stirring mixer is started and operated at a rotation speed of 300 rpm under normal pressure, and the diamine compound C is fed in batches within half an hour.

A reaction temperature is raised to 60° C. to dissolve all the solids in the reaction solution. At this time, the reaction solution has a yellowish brown color. A catalyst including 5 g of sodium acetate, 175 ml of acetic anhydride, and 35 ml of triethylamine are added into the reaction solution. The reaction temperature is further raised to 90° C. to carry out a synthesis reaction between the diamine compound C and the maleic anhydride, and a reaction time is 9 hours. After the reaction is completed, the reaction solution is turned from the clear yellowish brown color into a viscous reddish brown color. After a reddish brown resin powder is precipitated from the reaction solution, impurities such as unreacted monomers and residuals of acid are removed from the reddish brown resin powder, so that a high purity bismaleimide resin powder (hereinafter referred to as “BMI-C resin”) with a reddish brown color is obtained. A physical property test is performed on a copper clad laminate made from the BMI-C resin, and test results are shown in Table 1.

### Example 4

184 g of a diamine compound having a structure represented by formula (10) (hereinafter referred to as “diamine compound D”) and 15.54 g of maleic anhydride are dissolved in 300 ml of acetone to prepare a reaction solution. A molar ratio of the diamine compound D to the maleic anhydride is 4:1. The reaction solution is placed into a 1000 ml four-neck round bottom reaction flask that has a stirring mixer disposed therein, and nitrogen gas is introduced into the 1000 ml four-neck round bottom reaction flask to remove air and moisture. The stirring mixer is started and operated at a rotation speed of 300 rpm under normal pressure, and the diamine compound D is fed in batches within half an hour.

A reaction temperature is raised to 60° C. to dissolve all the solids in the reaction solution. At this time, the reaction solution has a yellowish brown color. A catalyst including 4 g of sodium acetate, 140 ml of acetic anhydride, and 28 ml of triethylamine are added into the reaction solution. The reaction temperature is further raised to 90° C. to carry out a synthesis reaction between the diamine compound D and the maleic anhydride, and a reaction time is 12 hours. After the reaction is completed, the reaction solution is turned from the clear yellowish brown color into a viscous reddish brown color. After a reddish brown resin powder is precipitated from the reaction solution, impurities such as unreacted monomers and residuals of acid are removed from the reddish brown resin powder, so that a high purity bismaleimide resin powder (hereinafter referred to as “BMI-D resin”) with a reddish brown color is obtained. A physical property test is performed on a copper clad laminate made from the BMI-D resin, and test results are shown in Table 1.

### Example 5

184 g of a diamine compound having a structure represented by formula (11) (hereinafter referred to as “diamine compound E”) and 17.47 g of maleic anhydride are dissolved in 430 ml of N,N-dimethylformamide (DMF) to prepare a reaction solution. A molar ratio of the diamine compound E to the maleic anhydride is 4:1. The reaction solution is placed into a 1000 ml four-neck round bottom reaction flask that has a stirring mixer disposed therein, and nitrogen gas is introduced into the 1000 ml four-neck round bottom reaction flask to remove air and moisture. The stirring mixer is started and operated at a rotation speed of 300 rpm under normal pressure, and the diamine compound E is fed in batches within half an hour.

A reaction temperature is raised to 60° C. to dissolve all the solids in the reaction solution. At this time, the reaction solution has a yellowish brown color. A catalyst including 4 g of sodium acetate, 140 ml of acetic anhydride, and 28 ml of triethylamine are added into the reaction solution. The reaction temperature is further raised to 90° C. to carry out a synthesis reaction between the diamine compound E and the maleic anhydride, and a reaction time is 10 hours. After the completion of the reaction, the reaction solution is turned into a viscous light yellow color from the clear yellowish brown color. Precipitating and purifying processes are performed on the reaction solution. After a light yellow resin powder is precipitated from the reaction solution, impurities such as unreacted monomers and residuals of acid are removed from the light yellow resin powder, so that a high purity bismaleimide resin powder (hereinafter referred to as “BMI-E resin”) with a light yellow color is obtained. A physical property test is performed on a copper clad laminate made from the BMI-E resin, and test results are shown in Table 1.

### Comparative Example

A physical property test is performed on a copper clad laminate made from a conventional bismaleimide resin (product name. BMI-5100, available from Daiwakasei Industry Co. Ltd), and test results are shown in Table 1.

TABLE 1

| | | | | | | Comparative |
|---|---|---|---|---|---|---|
| | Examples | | | | | Example |
| Items | 1 | 2 | 3 | 4 | 5 | (BMI-5100) |
| Tg (°C) | 215 | 255 | 274 | 204 | 213 | 225 |
| Dk (10GHz) | 2.55 | 2.58 | 2.81 | 2.54 | 2.38 | 2.65 |
| Df (10GHz) | 0.0027 | 0.0035 | 0.0031 | 0.0039 | 0.004 | 0.0041 |
| Solvent solubility | 60% | 65% | 70% | 40% | 40% | 30% |
| (%) | | | | | | |
| Product appearance | Dark | Dark | Reddish | Reddish | Light | |
| (Color of resin | brown | brown | brown | brown | yellow | |
| particles) | | | | | | |

In Table 1, the glass transition temperatures (Tg) are measured by a differential scanning calorimeter (TA 2100 DSC). The dielectric constants (Dk) and dissipation factors (Df) are measured by a dielectric analyzer (HP Agilent E4991A) at a frequency of 10 GHz. The solvent solubilities are measured by using acetone, and are represented by weight percentage.

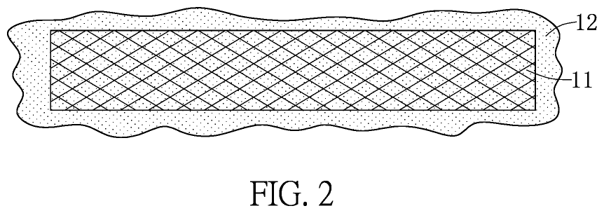

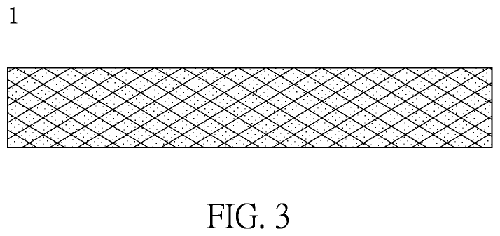

Referring to FIG. 2 and FIG. 3, the modified bismaleimide resin of the present disclosure can be used to manufacture a prepreg 1. More specifically, a resin material 12 including the modified bismaleimide resin can be applied to a substrate 11 (e.g., an insulating paper, a glass fiber cloth, or another fiber material) in an appropriate manner, and the resin material 12 is dried to a semi-cured state. In practice, the resin material 12 may be in the form of a resin varnish, and may be applied in a coating or impregnating manner.

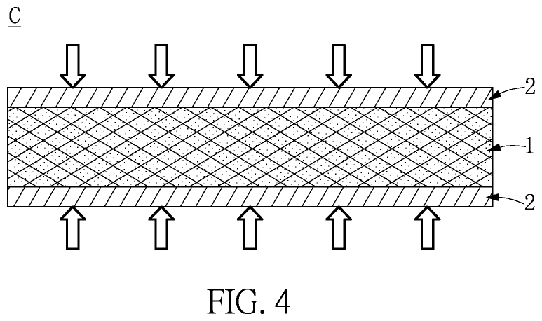

Referring to FIG. 4, the prepreg 1 can be used to manufacture a copper clad laminate C. More specifically, one or more copper foil layers 2 can be laminated on one or both sides of one or more of the prepregs 1, and then a hot pressing is performed. There are no particular restrictions on the hot pressing conditions (e.g., temperature and pressure), which can be adjusted according to a composition of the resin material 12.

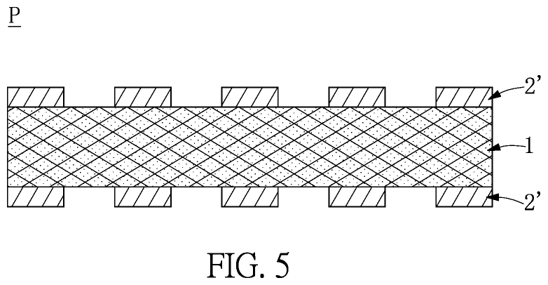

Referring to FIG. 5, the copper clad laminate C can be used to manufacture a printed circuit board P. More specifically, the printed circuit board P can be manufactured by patterning the copper foil layer 2 of the copper clad laminate C into a circuit. That is, the copper foil layer 2 is formed into a circuit layer 2′ with a specific circuit pattern. The copper foil layer 2 may be patterned by lithography and etching, but is not limited thereto.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A modified bismaleimide resin, characterized by having a structure represented by formula (1): 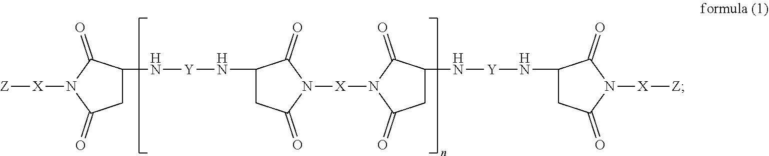
wherein in formula (1), X and Y each independently represent a group represented by formula (2) or (3), Z represents a group represented by formula (4), (5) or (6), and n represents an integer from 1 to 20; 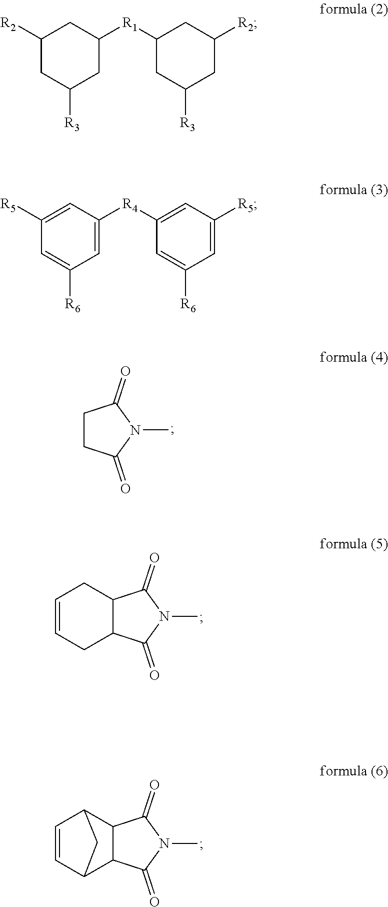
wherein R₁ in formula (2) and R₄ in formula (3) each independently represent a benzyl group or an alkyl group having 1 to 10 carbon atoms, and R₂ and R₃ in formula (2) and R₅ and R₆ in formula (3) each independently represent a hydrogen atom or an alkyl group having 1 to 10 carbon atoms.

2. The modified bismaleimide resin according to claim 1, wherein the modified bismaleimide resin has a dielectric constant (Dk) of less than 2.6 and a dissipation factor (Df) of less than 0.003 at 10 GHz.

3. The modified bismaleimide resin according to claim 1, wherein a water absorption rate of the modified bismaleimide resin is from 0.1% to 0.3%.

4. The modified bismaleimide resin according to claim 1, wherein the modified bismaleimide resin has a solubility in acetone of 42% and a solubility in butanone of 40%.

5. A prepreg obtained by applying a resin material that includes the modified bismaleimide resin as claimed in claim 1 onto a substrate and curing the resin material.

6. A copper clad laminate, comprising the prepreg as claimed in claim 5 and a copper foil layer attached to the prepreg.

7. A printed circuit board obtained by patterning the copper foil layer of the copper clad laminate as claimed in claim 6 into a circuit.

8. A method for preparing the modified bismaleimide resin as claimed in claim 1, comprising:
providing a reactor;
placing a reaction solution into the reactor, wherein the reaction solution includes a diamine compound, maleic anhydride, and a solvent, and a molar ratio of the diamine compound to the maleic anhydride is 1:2-20; and
adding a catalyst into the reaction solution to carry out a synthesis reaction between the diamine compound and the maleic anhydride.

9. The method according to claim 8, wherein the diamine compound has a structure represented by formula (7), (8), (9), (10), or (11):

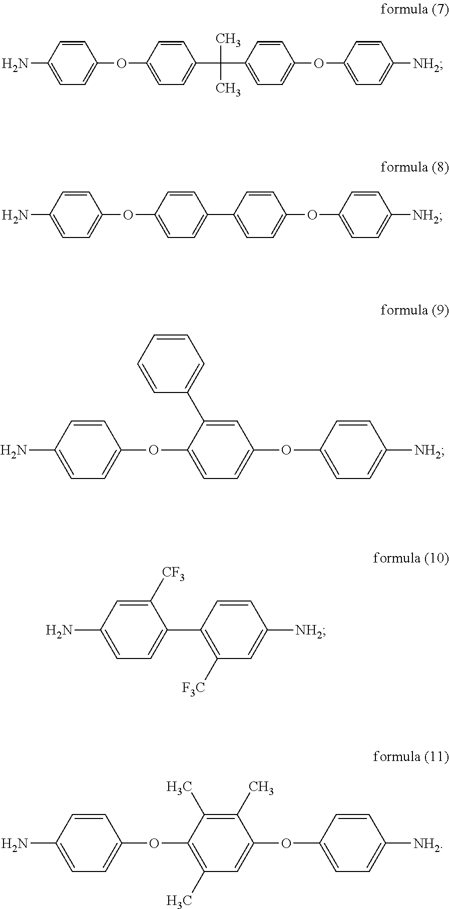 [SMILES: CC(C)(c1ccc(Oc2ccc(N)cc2)cc1)c1ccc(Oc2ccc(N)cc2)cc1 ; Nc1ccc(Oc2ccc(-c3ccc(Oc4ccc(N)cc4)cc3)cc2)cc1 ; Nc1ccc(Oc2ccc(Oc3ccc(N)cc3)c(-c3ccccc3)c2)cc1 ; Nc1ccc(-c2ccc(N)cc2C(F)(F)F)c(C(F)(F)F)c1 ; Cc1cc(Oc2ccc(N)cc2)c(C)c(C)c1Oc1ccc(N)cc1]

10. The method according to claim 8, wherein the synthesis reaction is carried out from 40° C. to 200° C. for 1 to 8 hours.

11. The method according to claim 8, wherein the solvent is acetone, toluene, N,N-dimethylformamide (DMF) or methyl isobutyl ketone (MIBK), and the catalyst includes sodium acetate, acetic anhydride and triethylamine.
